(19) United States
(12) Patent Application Publication
(10) Pub. No.: US 2025/0096743 A1
(43) Pub. Date: Mar. 20, 2025

(54) Wireless Circuitry with Tunable Matching Network

(71) Applicant: Apple Inc., Cupertino, CA (US)

(72) Inventors: Ahmed G Radwan, Munich (DE); Mina Mofreh Gad Elsayed Abdallah, Munich (DE)

(21) Appl. No.: 18/470,561

(22) Filed: Sep. 20, 2023

(51) Int. Cl. H03F 1/56; H03F 3/19

(52) U.S. Cl. CPC H03F 1/565; H03F 3/19; H03F 2200/387; H03F 2200/451

(57) ABSTRACT

Wireless circuitry can include a radio-frequency amplifier and a tunable matching network coupled to an output of the radio-frequency amplifier. The tunable matching network can include series inductors, first switches coupled between the output of the radio-frequency amplifier and a first portion of the series inductors, and second switches coupled between the first portion of the series inductors and an output port of the tunable matching network. The tunable matching network can further include an adjustable balun having a primary coil coupled to a second portion of the series inductors and having a secondary coil. The wireless circuitry can include control circuitry configured to activate and deactivate the first and second switches to operate the tunable matching network across a wide range of frequency bands.

### FIELD

This disclosure relates generally to electronic devices and, more particularly, to electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through a power amplifier, which is configured to amplify low power analog signals to higher power signals more suitable for transmission through the air over long distances. Radio-frequency signals received at an antenna can be fed through a low noise amplifier, which is configured to amplify low power analog signals to higher power signals for ease of processing at a receiver. It can be challenging to design satisfactory radio-frequency amplifier for an electronic device.

### SUMMARY

An electronic device may include wireless communications circuitry. The wireless communications circuitry may include one or more processors or signal processing blocks for generating baseband signals, a transceiver for upconverting (modulating) the baseband signals to radio frequencies and for downconverting (demodulating) radio-frequency signals to baseband signals, a radio-frequency power amplifier for amplifying radio-frequency signals prior to transmission at one or more antennas, and a radio-frequency low noise amplifier for amplifying radio-frequency signals received at one or more antennas in the electronic device. Radio-frequency power (transmitting) amplifiers and low noise (receiving) amplifiers are sometimes referred to collectively as radio-frequency amplifiers.

An aspect of the disclosure provides wireless circuitry that includes a radio-frequency amplifier and a tunable matching network that is coupled to an output of the radio-frequency amplifier. The tunable matching network can include a plurality of series inductors, a first plurality of switches coupled between the output of the radio-frequency amplifier and a first portion of the plurality of series inductors, and a second plurality of switches coupled between the first portion of the plurality of series inductors and an output port of the tunable matching network. The tunable matching network can include a balun having a primary coil coupled to a second portion, different than the first portion, of the plurality of series inductors and having a secondary coil, where the secondary coil has a first terminal coupled to a power supply line and a second terminal coupled to the output port of the tunable matching network. The tunable matching network can include a parallel inductor coupled to a portion of the second plurality of switches, a first switch coupled between first terminals of the primary coil and the parallel inductor, and a second switch coupled between second terminals of the primary coil and the parallel inductor. The wireless circuitry can further include control circuitry configured to selectively activate and deactivate the first and second plurality of switches in three or more frequency tuning modes of the tunable matching network.

An aspect of the disclosure provides wireless circuitry that includes a radio-frequency amplifier and a tunable matching network that is coupled to an output of the radio-frequency amplifier. The tunable matching network can include a plurality of series inductors, a first plurality of switches coupled between the output of and radio-frequency amplifier and a first portion of the plurality of series inductors, and a tunable balun coupled between the second portion, different than the first portion, of the plurality of series inductors and an output port of the tunable matching network. The tunable balun can include a primary coil coupled to the second portion of the plurality of series inductors and a secondary coil, where the secondary coil has a first terminal coupled to a ground line and a second terminal coupled to the output port of the tunable matching network. The tunable balun can further include a parallel inductor, a first switch coupled between first terminals of the primary coil and the parallel inductor, a second switch coupled between second terminals of the primary coil and the parallel inductor. The tunable matching network can further include a second plurality of switches coupled between the first portion of the plurality of series inductors and the output port of the tunable matching network.

An aspect of the disclosure provides wireless circuitry having a radio-frequency amplifier and a tunable matching network. The tunable matching network can include a first tuning stage, first switches coupled between an output of the radio-frequency amplifier and the first tuning stage, a second tuning stage, and second switches coupled between the second tuning stage and an output port of the tunable matching network. The first tuning stage can include first, second, third, and fourth series inductors, and the second tuning stage can include an adjustable transformer. The wireless circuitry can include control circuitry configured to adjust the first and second switches so that current flows through the first and second series inductors without flowing through the third and fourth series inductors. The control circuitry can further be configured to adjust the first and second switches so that the first and third series inductors are coupled in parallel and currents flowing through the first and third inductors are in a same direction, and so that the second and fourth series inductors are coupled in parallel and currents flowing through the second and fourth inductors are in a same direction. The control circuitry can further be configured to adjust the first and second switches so that the first and third series inductors are coupled in parallel and currents flowing through the first and third inductors are in an opposite direction, and so that the second and fourth series inductors are coupled in parallel and currents flowing through the second and fourth inductors are in an opposite direction.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having radio-frequency amplifiers in accordance with some embodiments.

FIG. 3 is a diagram of an illustrative tunable matching network coupled at an output of a radio-frequency amplifier in accordance with some embodiments.

FIG. 4 is a circuit diagram showing an implementation of the tunable matching network shown in FIG. 3 operable in at least five frequency modes in accordance with some embodiments.

FIG. 5 is a table summarizing the five frequency modes of the tunable matching network of FIG. 4 in accordance with some embodiments.

FIGS. 6A-6E illustrate different configurations corresponding to the five frequency modes of the tunable matching network of FIG. 4 in accordance with some embodiments.

FIG. 7 is a circuit diagram showing an implementation of the tunable matching network shown in FIG. 3 operable in at least four frequency modes in accordance with some embodiments.

FIG. 8 is a table summarizing the four frequency modes of the tunable matching network of FIG. 7 in accordance with some embodiments.

FIG. 9 is a circuit diagram showing an implementation of the tunable matching network shown in FIG. 3 operable in at least three frequency modes in accordance with some embodiments.

FIG. 10 is a table summarizing the three frequency modes of the tunable matching network of FIG. 9 in accordance with some embodiments.

FIG. 11 is a diagram of an illustrative tunable matching network that includes additional inductors and switches configured to further expand the total number of frequency modes in accordance with some embodiments.

### DETAILED DESCRIPTION

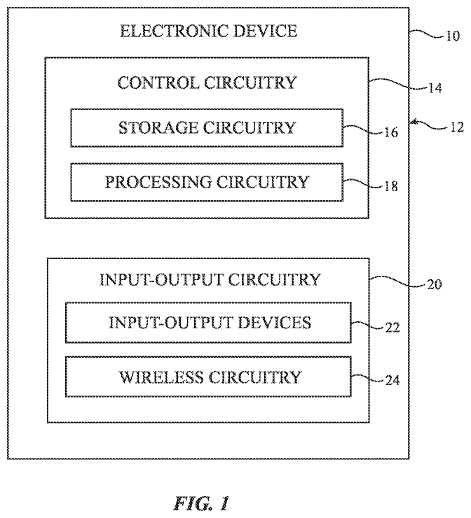

An electronic device such as device 10 of FIG. 1 may be provided with wireless circuitry. The wireless circuitry can include one or more radio-frequency transmitting amplifiers and radio-frequency receiving amplifiers. The radio-frequency transmitting amplifiers (power amplifiers) can have a matching network coupled at its output to provide the highest power and efficiency across a broad range of operating frequencies. To provide optimal efficiency over a broad bandwidth, the matching network can be provided with inductive tunability (as an example). The matching network may include a first inductive tuning stage (e.g., a first group of inductors), a second inductive tuning stage (e.g., a second group of inductors forming a balun), and associated switches for selectively activating a portion of the inductors in the first inductive tuning stage and/or a portion of the inductors in the second inductive tuning stage.

Depending on the number of switches and the number of inductors in the second inductive tuning stage, the matching network can be operable in at least 3 different frequency modes, at least 4 different frequency modes, at least 5 different frequency modes, or more than 5 different frequency modes. A tunable matching network configured in this way is technically advantageous and beneficial by providing flexibility, scalability, extended bandwidth across multiple frequency bands, increased power and improved efficiency between the various frequency bands, and improved harmonic rejection while minimizing circuit area and cost.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHZ), a 5 GHZ WLAN band (e.g., from 5180 to 5825 MHZ), a Wi-Fi® 6E band (e.g., from 5925-7125 MHZ), and/or other Wi-Fi® bands (e.g., from 1875-5160 MHZ), wireless personal area network (WPAN) frequency bands such as the 2.4 GHZ Bluetooth® band or other WPAN communications bands, cellular telephone frequency bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-300 GHz, near-field communications frequency bands (e.g., at 13.56 MHZ), satellite navigation frequency bands (e.g., a GPS band from 1565 to 1610 MHZ, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

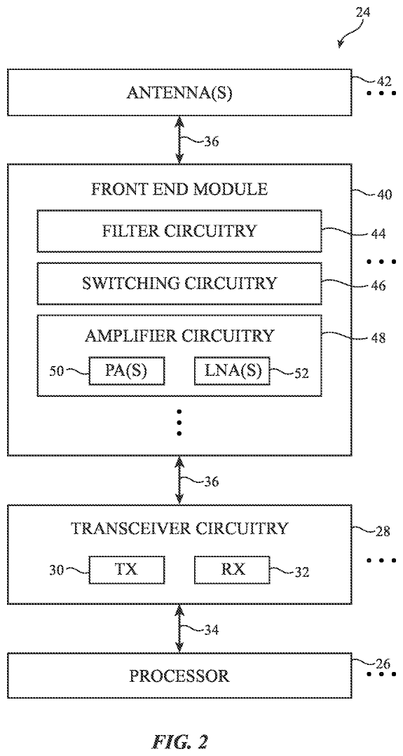

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26 into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHZ WLAN band (e.g., from 2400 to 2480 MHZ), a 5 GHZ WLAN band (e.g., from 5180 to 5825 MHZ), a Wi-Fi® 6E band (e.g., from 5925-7125 MHZ), and/or other Wi-Fi® bands (e.g., from 1875-5160 MHZ), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

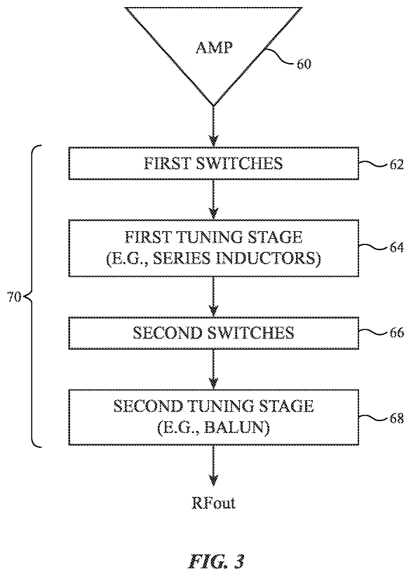

FIG. 3 is a diagram of an illustrative tunable matching network coupled at an output port of a radio-frequency amplifier such as amplifier 60. Amplifier 60 can represent a radio-frequency transmitting amplifier (e.g., power amplifier 50 in FIG. 2) or can represent a radio-frequency receiving amplifier (e.g., low noise amplifier 52 in FIG. 2). As shown in FIG. 3, a matching network such as tunable matching network 70 can be coupled at the output of amplifier 60. Tunable matching network 70 may include a first tuning circuit such as first tuning stage 64, a second tuning circuit such as second tuning stage 68, first switches 62 coupled between the output of amplifier 60 and first tuning stage 64, and second switches 66 coupled between first tuning stage 64 and second tuning stage 68. The first switches 62 are sometimes referred to collectively as a first plurality of switches. The second switches 66 are sometimes referred to collectively as a second plurality of switches.

The first tuning stage 64 can, for example, include one or more series inductors. The second tuning stage 68 can, for example, include one or more inductors forming a transformer or a balun. The second tuning stage 68 may be coupled to a radio-frequency output port RFout. This example in which the first and second tuning stages 64 and 68 are inductance based is illustrative. In other suitable embodiments, first tuning stage 64 can include one or more inductors, one or more capacitors, one or more resistors, and/or other electrical components that can be switched in and out of use to provide impedance matching. Similarly, second tuning stage 68 can include one or more inductors, one or more capacitors, one or more resistors, and/or other electrical components that can be switched in and out of use to provide impedance matching. Configured in this way, switches 62 and 66 can be selectively activated and deactivated so that matching network 70 can be tuned to provide proper impedance matching to ensure optimal power efficiency across multiple frequency bands.

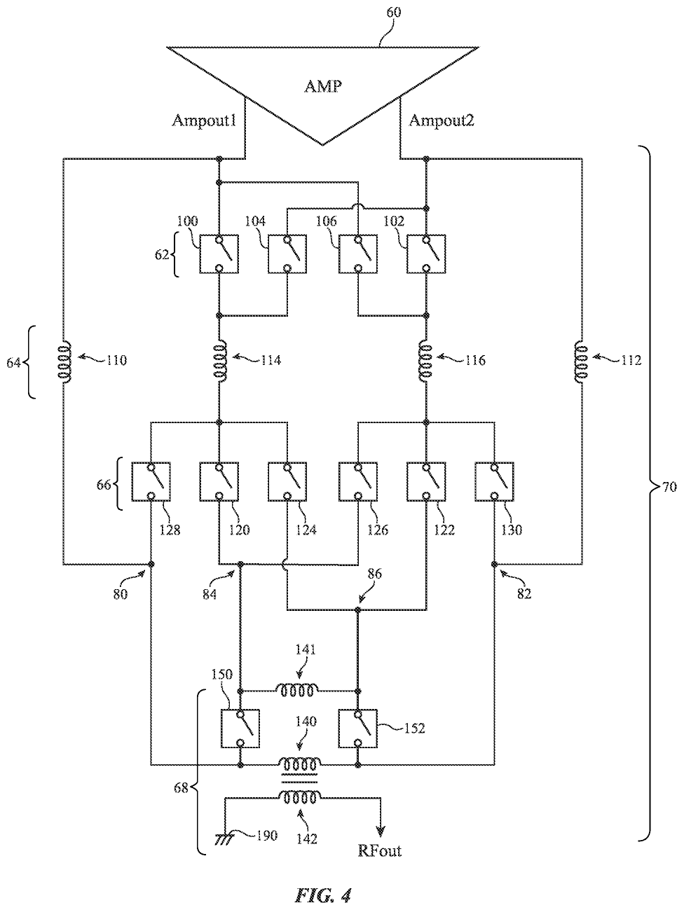

FIG. 4 is a circuit diagram showing an implementation of tunable matching network 70 of the type shown in FIG. 3 and is operable in at least five different frequency modes. As shown in FIG. 4, amplifier 60 may be a differential amplifier having a first output terminal Ampout1 and a second output terminal Ampout2. The first switches 62 can include one or more switches such as switches 100, 102, 104, and 106. The first tuning stage 64 can include one or more inductors such as series inductors 110, 112, 114, and 116. A tuning stage that includes inductors is sometimes referred to as an inductive tuning stage. The second switches can include one or more switches such as switches 120, 122, 124, 126, 128, and 130. The second tuning stage 68 can be implemented as a balun (sometimes referred to as a transformer) with additional switches 150 and 152.

Series inductor 110 may have a first terminal coupled to the first amplifier output terminal Ampout1 and may have a second terminal coupled to node 80. Series inductor 112 may have a first terminal coupled to the second amplifier output terminal Ampout2 and may have a second terminal coupled to node 82. Series inductor 114 may have a first terminal coupled to a first portion of switches 62 and a second terminal coupled to a first portion of switches 66. Series inductor 116 may have a first terminal coupled to a second portion of switches 62 and a second terminal coupled to a second portion of switches 66. In particular, switch 100 may be coupled between Ampout1 and the first terminal of inductor 114. Switch 102 may be coupled between Ampout2 and the first terminal of inductor 116. Switch 104 may be coupled between Ampout2 and the first terminal of inductor 114. Switch 106 may be coupled between Ampout1 and the first terminal of inductor 116.

Turning now to the second switches 66, switch 120 may be couped between the second terminal of inductor 114 and node 84. Switch 122 may be coupled between the second terminal of inductor 116 and node 86. Switch 124 may be coupled between the second terminal of inductor 114 and node 86. Switch 126 may be coupled between the second terminal of inductor 116 and node 84. Switch 128 may be coupled between the second terminal of inductor 114 and node 80. Switch 130 may be coupled between the second terminal of inductor 116 and node 82. The second tuning stage 68 may include a balun having a primary coil 140 and a secondary coil 142. Primary coil 140 may have a first terminal coupled to node 80 and a second terminal coupled to node 82. Secondary coil 142 may have a first terminal coupled to a ground power supply line 190 (e.g., a ground line on which ground voltage Vss is provided) and a second terminal coupled to a radio-frequency output port RFout. Second tuning stage 68 may further include an additional inductor (coil) 141 that can be selectively coupled in parallel with primary coil 140 through switches 150 and 152. Inductor 141 may have a first terminal coupled to node 84 and a second terminal coupled to node 86. Switch 150 may be coupled between nodes 80 and 84. Switch 152 may be coupled between nodes 82 and 86. Inductor 141 can be coupled in parallel with primary coil 140 via switches 150 and 152 and can sometimes be referred to as a parallel inductor.

Tunable matching network 70 configured in this way may be operable in a plurality of frequency modes depending the state of switches 62 and 66 and also switches 150 and 152 in the second tuning stage 68. All of these switches can be activated and deactivated by control circuitry 14 in FIG. 1, one or more processors in circuitry 18 of FIG. 1, one or more circuits within transceiver circuity 28 of FIG. 2, one or more processors 26 of FIG. 2, or other control circuit within device 10.

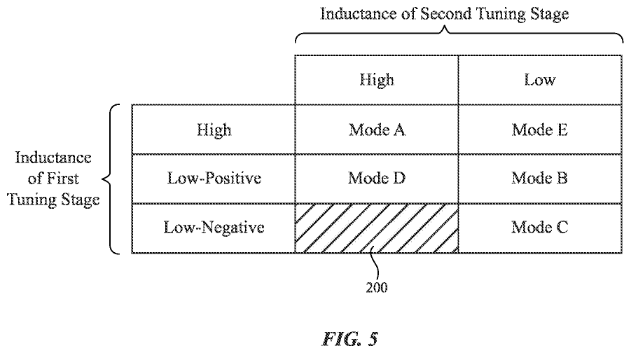

FIG. 5 is a table summarizing at least five frequency modes of tunable matching network 70 of the type described in connection with FIG. 4. As shown in FIG. 5, the first tuning stage 64 can be adjusted to provide a “high” inductance, a “low-positive” magnetic inductance, or a “low-negative” magnetic inductance. The high inductance can be achieved when only series inductors 110 and 112 are activated (while series inductors 114 and 116 are deactivated). The term “activated” when referring to an inductor can refer to and be defined herein as an active state where current is flowing through that inductor. Conversely, the term “deactivated” when referring to an inductor can refer to and be defined herein as an idle state where no current is flowing through that inductor.

The low-positive magnetic inductance can be achieved when all of inductors 110, 112, 114, and 116 are activated, but the currents flowing through inductors 110 and 114 are in the same direction while the currents flowing through inductors 112 and 116 are also in the same direction. The low-negative magnetic inductance can be achieved when all of inductors 110, 112, 114, and 116 are activated, but the currents flowing through inductors 110 and 114 are in the opposing direction while the currents flowing through inductors 112 and 116 are also in the opposite direction.

The second tuning stage 68 can be adjusted to provide a “high” inductance or a “low” inductance. The high inductance of second tuning stage 68 can be achieved when current is only flowing through primary coil 140 and not flowing through additional coil 141. The low inductance of second tuning stage 68 can be achieved when current is flowing through both coils 140 and 141 in the same direction.

The combination of a high inductance at the first tuning stage and a high inductance at the second tuning stage corresponds to a first mode A suitable for operating at a first frequency. The combination of a low-positive inductance at the first tuning stage and a low inductance at the second tuning stage corresponds to a second mode B suitable for operating at a second frequency different than the first frequency. The combination of a low-negative inductance at the first tuning stage and a low inductance at the second tuning stage corresponds to a third mode C suitable for operating at a third frequency different than the first and second frequencies. The combination of a low-positive inductance at the first tuning stage and a high inductance at the second tuning stage corresponds to a fourth mode D suitable for operating at a fourth frequency different than the first, second, and third frequencies. The combination of a high inductance at the first tuning stage and a low inductance at the second tuning stage corresponds to a fifth mode E suitable for operating at a fifth frequency different than the first, second, third, and fourth frequencies.

The combination of a low-negative inductance at the first tuning stage and a high inductance at the second tuning stage (as indicated by shaded region 200) might not be achievable by the circuit arrangement of FIG. 4. Modifications to existing connections may be needed to support a mode corresponding to this last combination. To accomplish this, switch 128 may be rewired such that it is coupled between the second terminal of inductor 114 and node 82, whereas switch 130 may be rewired such that it is coupled between the second terminal of inductor 130 and node 80. Mode D may not be achievable in this rewired arrangement.

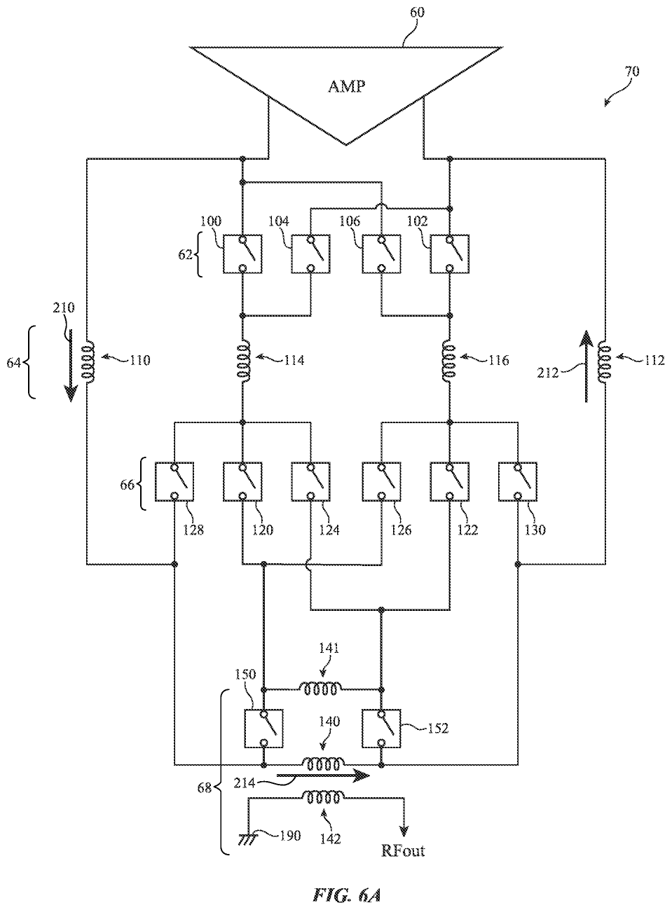

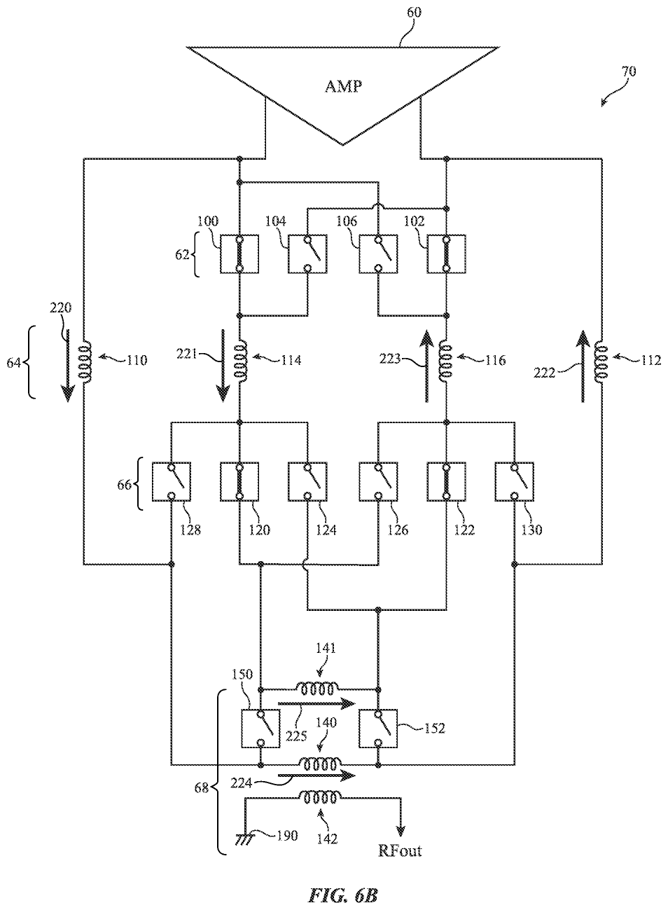

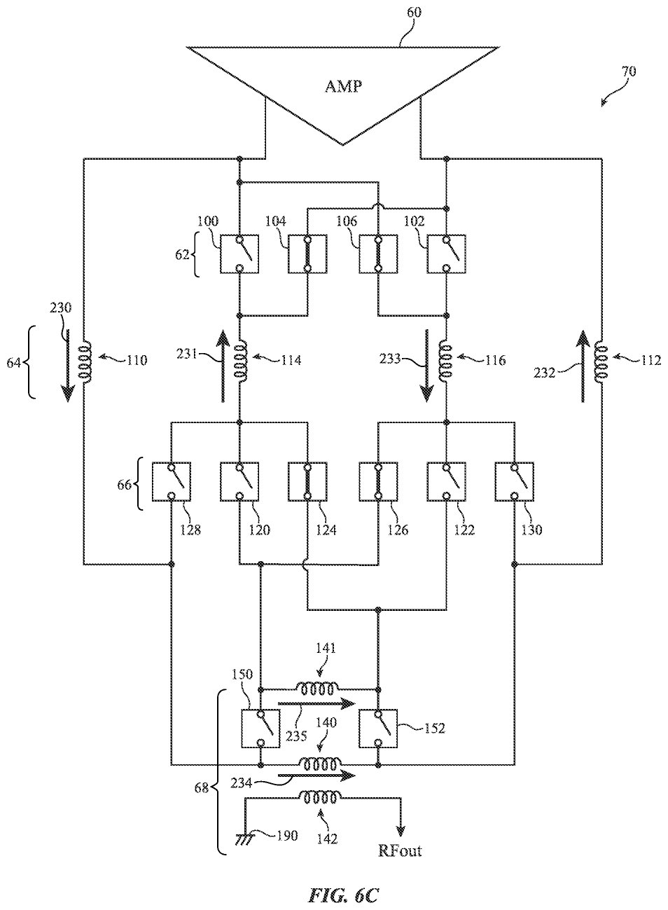

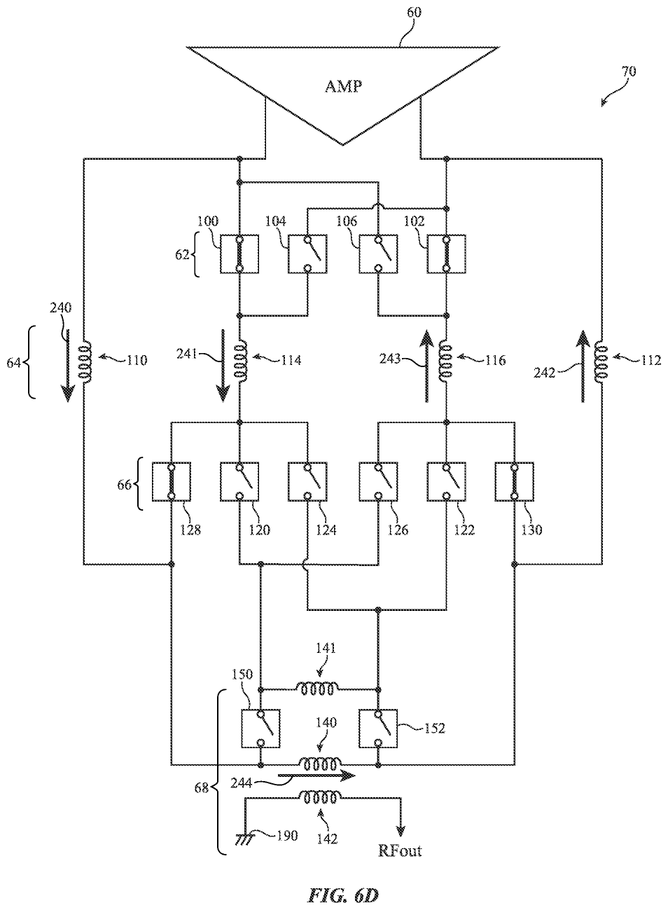

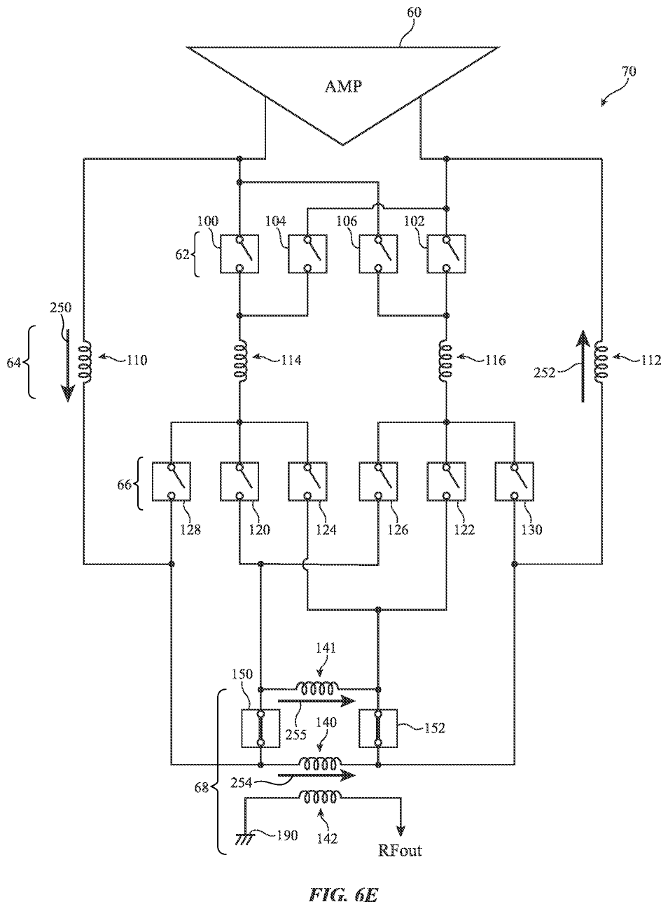

FIGS. 6A-6E illustrate different configurations corresponding to the five operation modes A, B, C, D, and E described above in connection with FIG. 5. FIG. 6A shows a snapshot of tunable matching network 70 during mode A. As shown in FIG. 6A, none of the switches 62, 66, 150, and 152 are activated. The term “activate” with respect to a switch may refer to or be defined herein as an action that places the switch in an on or low-impedance state such that the two terminals of the switch are electrically connected to conduct current. The term “deactivate” with respect to a switch may refer to or be defined herein as an action that places the switch in an off or high-impedance state such that the two terminals of the switch/transistor are electrically disconnected with minimal leakage current. Configured in this way, current can flow through inductor 110 (as indicated by the direction of arrow 210), through primary coil 140 (as indicated by the direction of arrow 214), and through inductor 112 (as indicated by the direction of arrow 212). The terms “inductor,” “inductance,” “coil,” and “winding” all refer to a passive inductive structure and can sometimes be used interchangeably herein. This mode of operation corresponds to the first tuning stage 64 having a high inductance and the second tuning stage 68 also having a high inductance, which may provide proper impedance matching at the output of an amplifier during operation in a first radio-frequency band.

FIG. 6B shows a snapshot of tunable matching network 70 during mode B. As shown in FIG. 6B, only switches 100, 102, 120, and 122 are activated while all other switches are deactivated. Configured in this way, current can flow through inductor 110 (as indicated by the direction of arrow 220), through inductor 114 (as indicated by the direction of arrow 221), through primary coil 140 (as indicated by the direction of arrow 224), through additional coil 141 (as indicated by the direction of arrow 225), through inductor 112 (as indicated by the direction of arrow 222), and through inductor 116 (as indicated by the direction of arrow 223). In this mode, inductors 110 and 114 can be considered to be coupled in parallel; and inductors 112 and 116 can be considered to be coupled in parallel. Since the direction of current flow through each pair of parallel inductors is the same, a low-positive magnetic inductance is provided at the first tuning stage 64. Thus, this mode of operation corresponds to the first tuning stage 64 having a low-positive inductance and the second tuning stage 68 also having a low inductance, which may provide proper impedance matching at the output of an amplifier during operation in a second radio-frequency band different than the first radio-frequency band.

FIG. 6C shows a snapshot of tunable matching network 70 during mode C. As shown in FIG. 6C, only switches 104, 106, 124, and 126 are activated while all other switches in network 70 are deactivated. Configured in this way, current can flow through inductor 110 (as indicated by the direction of arrow 230), through inductor 114 (as indicated by the direction of arrow 231), through primary coil 140 (as indicated by the direction of arrow 234), through additional coil 141 (as indicated by the direction of arrow 235), through inductor 112 (as indicated by the direction of arrow 232), and through inductor 116 (as indicated by the direction of arrow 233). In this mode, inductors 110 and 114 can be considered to be coupled in parallel; and inductors 112 and 116 can be considered to be coupled in parallel. Since the current flow through each pair of parallel inductors is in opposite directions, a low-negative magnetic inductance is provided at the first tuning stage 64. Thus, this mode of operation corresponds to the first tuning stage 64 having a low-negative inductance and the second tuning stage 68 also having a low inductance, which may provide proper impedance matching at the output of an amplifier during operation in a third radio-frequency band different than the first and second radio-frequency bands.

FIG. 6D shows a snapshot of tunable matching network 70 during mode D. As shown in FIG. 6D, only switches 100, 102, 128, and 130 are activated while all other switches in network 70 are deactivated. Configured in this way, current can flow through inductor 110 (as indicated by the direction of arrow 240), through inductor 114 (as indicated by the direction of arrow 241), through primary coil 140 (as indicated by the direction of arrow 244), through inductor 112 (as indicated by the direction of arrow 242), and through inductor 116 (as indicated by the direction of arrow 243). Since switches 120, 122, 124, and 126 are all deactivated, no current flows through inductor 141. Thus, this mode of operation corresponds to the first tuning stage 64 having a low-positive inductance and the second tuning stage 68 having a high inductance, which may provide proper impedance matching at the output of an amplifier during operation in a fourth radio-frequency band different than the first, second, and third radio-frequency bands.

FIG. 6E shows a snapshot of tunable matching network 70 during mode E. As shown in FIG. 6E, only switches 150 and 152 within second tuning stage 68 are activated while all other switches in network 70 are deactivated. Configured in this way, current can flow through inductor 110 (as indicated by the direction of arrow 250), through primary coil 140 (as indicated by the direction of arrow 254), through additional inductor 141 (as indicated by the direction of arrow 255), and through inductor 112 (as indicated by the direction of arrow 252). Although all of switches 66 are deactivated, the activation of switches 150 and 152 allows at least some of the current flowing through primary coil 140 to be diverted into inductor 141. Thus, this mode of operation corresponds to the first tuning stage 64 having a high inductance (since inductors 114 and 116 are deactivated or idle here) and the second tuning stage 68 having a low inductance, which may provide proper impedance matching at the output of an amplifier during operation in a fifth radio-frequency band different than the first, second, third, and fourth radio-frequency bands.

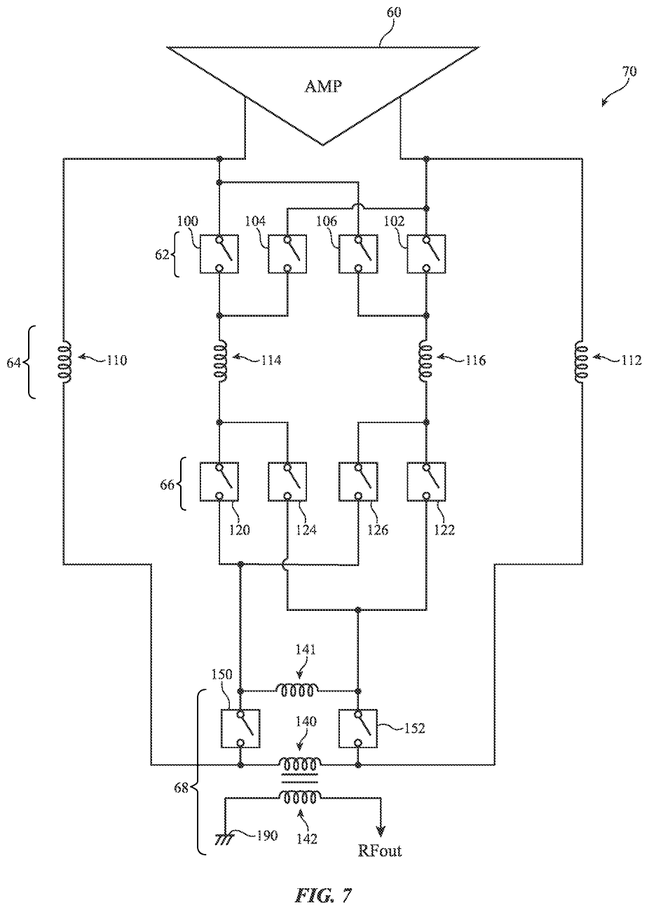

The embodiment of FIG. 4 in which second switches 66 include six switches 120, 122, 124. 126, 128, and 130 is exemplary. FIG. 7 illustrates another embodiment of tunable matching network 70 in which the second switches 66 include only four switches 120, 122, 124, and 126 (e.g., switches 128 and 130 are omitted). The remaining structure of FIG. 7 is identical to that already described in connection with FIG. 4 and need not be reiterated in detail to avoid obscuring the present embodiment.

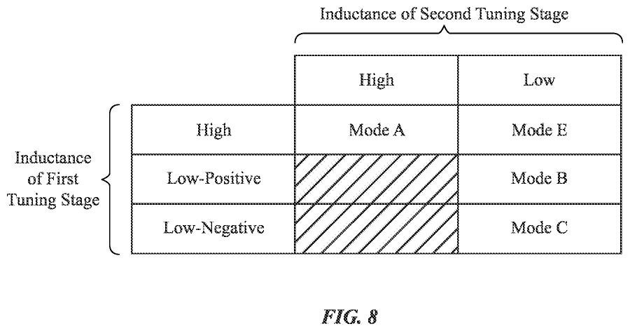

FIG. 8 is a table summarizing at least four frequency modes of tunable matching network 70 of the type shown in FIG. 7. As shown in FIG. 8, the first tuning stage 64 can be adjusted to provide a “high” inductance, a “low-positive” magnetic inductance, or a “low-negative” magnetic inductance. The high inductance can be achieved when only series inductors 110 and 112 are activated (while series inductors 114 and 116 are deactivated). The low-positive magnetic inductance can be achieved when all of inductors 110, 112, 114, and 116 are activated, but the currents flowing through inductors 110 and 114 are in the same direction while the currents flowing through inductors 112 and 116 are also in the same direction. The low-negative magnetic inductance can be achieved when all of inductors 110, 112. 114, and 116 are activated, but the currents flowing through inductors 110 and 114 are in the opposing direction while the currents flowing through inductors 112 and 116 are also in the opposite direction. The second tuning stage 68 can be adjusted to provide a “high” inductance or a “low” inductance. The high inductance of second tuning stage 68 can be achieved when current is only flowing through primary coil 140 and not flowing through additional coil 141. The low inductance of second tuning stage 68 can be achieved when current is flowing through both coils 140 and 141 in the same direction.

The combination of a high inductance at the first tuning stage and a high inductance at the second tuning stage corresponds to a first mode A suitable for operating at a first frequency. The combination of a low-positive inductance at the first tuning stage and a low inductance at the second tuning stage corresponds to a second mode B suitable for operating at a second frequency different than the first frequency. The combination of a low-negative inductance at the first tuning stage and a low inductance at the second tuning stage corresponds to a third mode C suitable for operating at a third frequency different than the first and second frequencies. The combination of a high inductance at the first tuning stage and a low inductance at the second tuning stage corresponds to a fourth mode E suitable for operating at a fourth frequency different than the first, second, and third frequencies.

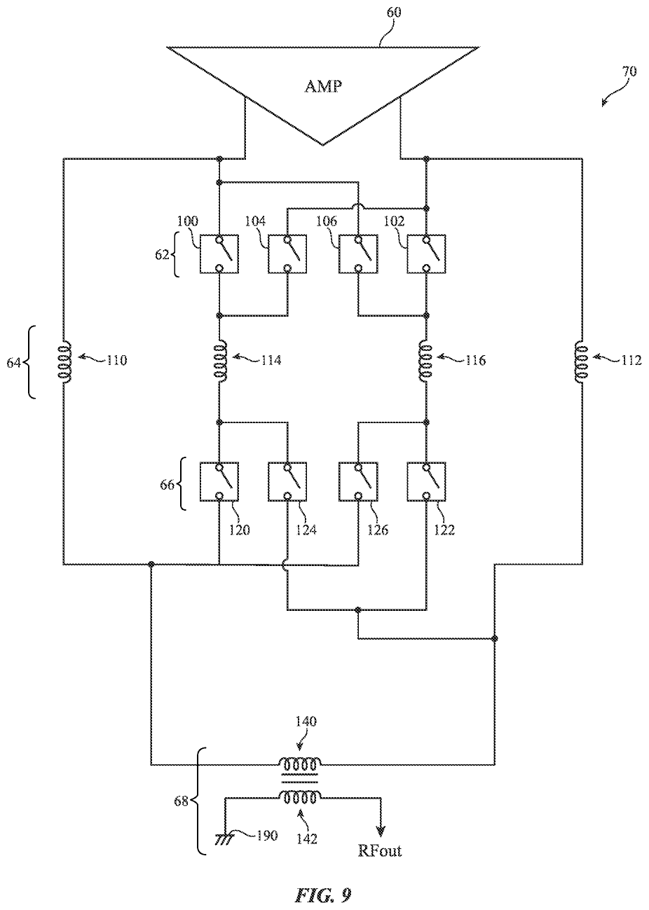

The embodiment of FIG. 7 in which the second tuning stage 68 includes additional coil 141 and switches 150 and 152 is exemplary. FIG. 9 illustrates another embodiment of tunable matching network 70 in which inductor 141 and switches 150,152 are omitted from the second tuning stage 68. The remaining structure of FIG. 9 is identical to that already described in connection with FIGS. 4 and 7 and need not be reiterated in detail to avoid obscuring the present embodiment.

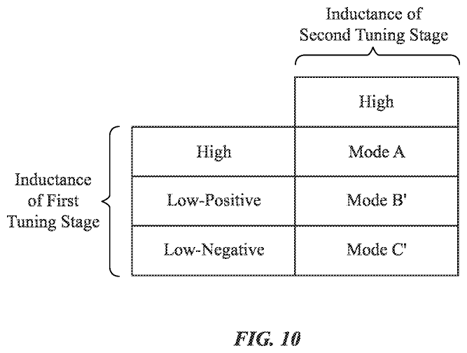

FIG. 10 is a table summarizing at least three frequency modes of tunable matching network 70 of the type shown in FIG. 9. As shown in FIG. 10, the first tuning stage 64 can be adjusted to provide a “high” inductance, a “low-positive” magnetic inductance, or a “low-negative” magnetic inductance. The high inductance can be achieved when only series inductors 110 and 112 are activated (while series inductors 114 and 116 are deactivated). The low-positive magnetic inductance can be achieved when all of inductors 110, 112, 114, and 116 are activated, but the currents flowing through inductors 110 and 114 are in the same direction while the currents flowing through inductors 112 and 116 are also in the same direction. The low-negative magnetic inductance can be achieved when all of inductors 110, 112, 114, and 116 are activated, but the currents flowing through inductors 110 and 114 are in the opposing direction while the currents flowing through inductors 112 and 116 are also in the opposite direction. The second tuning stage 68 simply provides a “high” inductance.

The combination of a high inductance at the first tuning stage and a high inductance at the second tuning stage corresponds to a first mode A suitable for operating at a first frequency. The combination of a low-positive inductance at the first tuning stage and the high inductance at the second tuning stage corresponds to a second mode B′ suitable for operating at a second frequency different than the first frequency. The combination of a low-negative inductance at the first tuning stage and the high inductance at the second tuning stage corresponds to a third mode C′ suitable for operating at a third frequency different than the first and second frequencies.

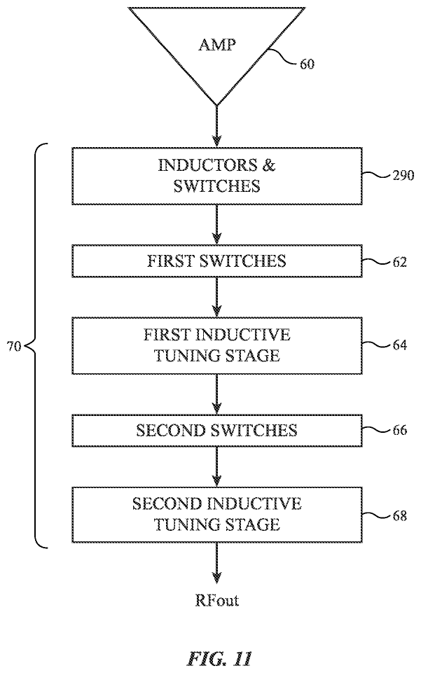

The embodiment of FIG. 3 in which tunable matching network 70 includes first switches 62, first tuning stage 64, second switches 66, and second tuning stage 68 is illustrative. In the example of FIGS. 9-10, tunable matching network 70 can be configured to provide at least three different frequency modes. In the example of FIGS. 7-8, tunable matching network 70 can be configured to provide at least four different frequency modes. In the example of FIGS. 4-6, tunable matching network 70 can be configured to provide at least five different frequency modes. FIG. 11 shows another embodiment in which tunable matching network 70 is provided with additional inductors and switches 290 coupled between the output of amplifier 60 and the first switches 62. The additional components 290 can include at least two additional inductors and a plurality of switches for introducing additional inductance at the output of amplifier 60. Configured in this way, the total number of modes can be multiplied by a factor of N, where N is any integer equal to or greater than one.

For example, if components 290 are configured to provide an N of 2 and the remainder of matching network 70 is implemented as shown in FIG. 4, then the total number of supported frequency modes can be equal to 10 (e.g., 5*2). As another example, if components 290 are configured to provide an N of 3 and the remainder of matching network 70 is implemented as shown in FIG. 4, then the total number of supported frequency modes can be equal to 15 (e.g., 5*3). As another example, if components 290 are configured to provide an N of 4 and the remainder of matching network 70 is implemented as shown in FIG. 4, then the total number of supported frequency modes can be equal to 20 (e.g., 5*4). As another example, if components 290 are configured to provide an N of 3 and the remainder of matching network 70 is implemented as shown in FIG. 7, then the total number of supported frequency modes can be equal to 12 (e.g., 4*3).

The methods and operations described above in connection with FIGS. 1-11 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. Wireless circuitry comprising:
a radio-frequency amplifier; and
a tunable matching network that is coupled to an output of the radio-frequency amplifier and that includes
a plurality of series inductors,
a first plurality of switches coupled between the output of the radio-frequency amplifier and a first portion of the plurality of series inductors, and
a second plurality of switches coupled between the first portion of the plurality of series inductors and an output port of the tunable matching network.

2. The wireless circuitry of claim 1, wherein the tunable matching network further comprises:
a balun having a primary coil coupled to a second portion, different than the first portion, of the plurality of series inductors and having a secondary coil, wherein the secondary coil has a first terminal coupled to a power supply line and a second terminal coupled to the output port of the tunable matching network.

3. The wireless circuitry of claim 2, wherein the tunable matching network further comprises:
a parallel inductor coupled to a portion of the second plurality of switches;
a first switch coupled between first terminals of the primary coil and the parallel inductor; and
a second switch coupled between second terminals of the primary coil and the parallel inductor.

4. The wireless circuitry of claim 2, wherein
a first series inductor in the plurality of series inductors has a first terminal coupled to a first amplifier output of the radio-frequency amplifier and has a second terminal coupled to a first terminal of the primary coil, and
a second series inductor in the plurality of series inductors has a first terminal coupled to a second amplifier output of the radio-frequency amplifier and has a second terminal coupled to a second terminal of the primary coil.

5. The wireless circuitry of claim 4, wherein
a third series inductor in the plurality of series inductors has a first terminal coupled to a first half of the first plurality of switches and has a second terminal coupled to a first half of the second plurality of switches, and
a fourth series inductor in the plurality of series inductors has a first terminal coupled to a second half, different than the first half, of the first plurality of switches and has a second terminal coupled to a second half, different than the first half, of the second plurality of switches.

6. The wireless circuitry of claim 5, wherein the first plurality of switches comprises:
a first switch coupled between the first amplifier output and the first terminal of the third series inductor; and
a second switch coupled between the second amplifier output and the first terminal of the fourth series inductor.

7. The wireless circuitry of claim 6, wherein the first plurality of switches further comprises:
a third switch coupled between the second amplifier output and the first terminal of the third series inductor; and
a fourth switch coupled between the first amplifier output and the first terminal of the fourth series inductor.

8. The wireless circuitry of claim 5, wherein the second plurality of switches comprises:
a first switch coupled between the second terminal of the third series inductor and the second terminal of the first series inductor; and
a second switch coupled between the second terminal of the fourth series inductor and the second terminal of the second series inductor.

9. The wireless circuitry of claim 5, wherein the second plurality of switches further comprises:
a third switch coupled between the second terminal of the third series inductor and the second terminal of the second series inductor; and
a fourth switch coupled between the second terminal of the fourth series inductor and second terminal of the first series inductor.

10. The wireless circuitry of claim 5, wherein the second plurality of switches further comprises:
a fifth switch having a first terminal directly coupled to the second terminal of the third series inductor and having a second terminal directly coupled to the second terminal of the first series inductor; and
a sixth switch having a first terminal directly coupled to the second terminal of the fourth series inductor and having a second terminal directly coupled to the second terminal of the second series inductor.

11. The wireless circuitry of claim 1, further comprising:
control circuitry configured to selectively activate and deactivate the first and second plurality of switches in three or more frequency tuning modes of the tunable matching network.

12. Wireless circuitry comprising:
a radio-frequency amplifier; and
a tunable matching network that is coupled to an output of the radio-frequency amplifier and that includes
a plurality of series inductors,
a first plurality of switches coupled between the output of and radio-frequency amplifier and a first portion of the plurality of series inductors, and
a tunable balun coupled between the second portion, different than the first portion, of the plurality of series inductors and an output port of the tunable matching network.

13. The wireless circuitry of claim 12, wherein the tunable balun comprises:
a primary coil coupled to the second portion of the plurality of series inductors; and
a secondary coil, wherein the secondary coil has a first terminal coupled to a ground line and a second terminal coupled to the output port of the tunable matching network.

14. The wireless circuitry of claim 13, wherein the tunable balun further comprises:
a parallel inductor;
a first switch coupled between first terminals of the primary coil and the parallel inductor; and
a second switch coupled between second terminals of the primary coil and the parallel inductor.

15. The wireless circuitry of claim 13, wherein the tunable matching network further comprises:
a second plurality of switches coupled between the first portion of the plurality of series inductors and the output port of the tunable matching network.

16. The wireless circuitry of claim 15, wherein the plurality of series inductors comprises:
a first series inductor coupled between a first amplifier output of the radio-frequency amplifier and a first terminal of the primary coil;
a second series inductor coupled between a second amplifier output of the radio-frequency amplifier and a second terminal of the primary coil;
a third series inductor coupled between a first portion of the first plurality of switches and a first portion of the second plurality of switches; and
a fourth series inductor coupled between a second portion of the first plurality of switches and a second portion of the second plurality of switches.

17. Wireless circuitry comprising:
a radio-frequency amplifier; and
a tunable matching network that includes
a first tuning stage,
first switches coupled between an output of the radio-frequency amplifier and the first tuning stage,
a second tuning stage, and
second switches coupled between the second tuning stage and an output port of the tunable matching network.

18. The wireless circuitry of claim 17, wherein the first tuning stage comprises first, second, third, and fourth series inductors, and wherein the second tuning stage comprises an adjustable transformer, further comprising:
control circuitry configured to adjust the first and second switches so that current flows through the first and second series inductors without flowing through the third and fourth series inductors.

19. The wireless circuitry of claim 18, wherein the control circuitry is further configured to adjust the first and second switches so that
the first and third series inductors are coupled in parallel and currents flowing through the first and third inductors are in a same direction, and
the second and fourth series inductors are coupled in parallel and currents flowing through the second and fourth inductors are in a same direction.

20. The wireless circuitry of claim 18, wherein the control circuitry is further configured to adjust the first and second switches so that
the first and third series inductors are coupled in parallel and currents flowing through the first and third inductors are in an opposite direction, and
the second and fourth series inductors are coupled in parallel and currents flowing through the second and fourth inductors are in an opposite direction.
